(19) United States
(12) Patent Application Publication
(10) Pub. No.: US 2021/0296524 A1
(43) Pub. Date: Sep. 23, 2021

(54) SiGeSn VIRTUAL SUBSTRATE FORMED BY MOLECULAR BEAM EPITAXY ON A Si SUBSTRATE FOR THE STRAINED GROWTH OF GeSn

(71) Applicant: The Government of the United States of America, as represented by the Secretary of the Navy, Arlington, VA (US)

(72) Inventors: Glenn G. Jernigan, Waldorf, MD (US); Mark E. Twigg, Falls Church, VA (US); Nadeemullah A. Mahadik, Springfield, VA (US); Jill A. Nolde, Takoma Park, MD (US)

(21) Appl. No.: 17/209,133

(22) Filed: Mar. 22, 2021

Related U.S. Application Data
(60) Provisional application No. 62/993,186, filed on Mar. 23, 2020.

(51) Int. Cl. H01L 31/18; H01L 31/0312; H01L 31/0392; C30B 29/52; C30B 23/02; C23C 16/06

(52) U.S. Cl. CPC H01L 31/1812; H01L 31/0312; C23C 16/06; C30B 29/52; C30B 23/025; H01L 31/03921

(57) ABSTRACT

A method of growing fully relaxed SiGeSn buffer layers on Si substrates to produce virtual substrates for the epitaxial growth of high quality GeSn films suitable for high performance infrared (IR) optoelectronic device technology directly integrated on silicon. Growing the SiGeSn virtual substrate uses a precisely decreasing growth temperature and Si flux and a precisely increasing Ge and Sn flux. The virtual substrates may have a slightly larger lattice constant than that of the target GeSn alloy to impose a precise degree of tensile strain resulting in a direct band gap for the target GeSn alloy.

### PRIORITY CLAIM

The present application is a non-provisional application claiming the benefit of U.S. Provisional Application No. 62/993,186 filed on Mar. 23, 2020, by Glenn G. Jernigan et al., entitled “SiGeSn VIRTUAL SUBSTRATE FORMED BY MOLECULAR BEAM EPITAXY ON A Si SUBSTRATE FOR THE STRAINED GROWTH OF GeSn,” the entire contents of which is incorporated herein by reference.

### BACKGROUND OF THE INVENTION

### Field of the Invention

The present invention relates generally to the epitaxial growth of high quality GeSn films, and more specifically to the use of fully relaxed SiGeSn buffer layers grown on Si substrates to produce virtual substrates for the epitaxial growth of high quality GeSn films suitable for high performance infrared (IR) optoelectronic device technology directly integrated on silicon.

### Description of the Prior Art

IR optoelectronic technology is becoming increasingly important in modern society. Commercially, IR optoelectronic materials play a major role in sending and receiving light through fiber optic lines for high speed, low loss communication. It is also used for light detection and ranging (LIDAR) systems, a key component of autonomous vehicle technology. There are also many critical military applications, including infrared sensing to detect, track, and image objects through their thermal emission under low visible illumination conditions.

At the heart of IR optoelectronic technology are high quality materials with direct, narrow bandgaps that can efficiently absorb IR photons and conduct the photo-generated free carriers to electrical contacts, or convert injected electrical current into IR emission. While silicon itself is not such a material, there are a number of material systems suitable for IR emitters and detectors, including III-V (e.g. InGaAs, InSb) and II-VI (e.g. HgCdTe, PbS) compound semiconductors.

The usefulness of these materials in optoelectronic technology, however, is dependent on their integration with silicon based electronics, which is required to control and process IR emitter and sensor signals. This leads to a major drawback of III-V and II-VI based IR optoelectronics, in that these materials cannot be directly grown on Si substrates and are not compatible with the processing steps utilized in producing Si CMOS technology. As a result, IR optoelectronic devices such as III-V based IR focal plane arrays (FPAs) are typically made by using a complicated materials engineering process to make hybrid III-V silicon structures. In broad outline, a wafer of the Ill-V material is independently processed to define multiple arrays of sensor pixels, onto which indium “bumps” are deposited through a lithographic process onto contacts on each pixel. The III-V wafer is then diced into individual sensor array “dies,” which are then hybridized to silicon readout integrated circuit (ROIC) dies, which have been similarly preprocessed and typically also decorated with indium bumps. This step is accomplished using highly sophisticated bump bonding equipment to secure and flip the III-V die, and then align it over the Si ROIC. Then a precise pressure is applied to cold-weld the indium bumps, typically followed by heating to ensure good electrical connection. Next, an epoxy is introduced, which infills and hardens within the regions between bumps, to stabilize the hybrid structure. The hybrid structure is then mounted in an appropriate package. Finally, the III-V substrate material is typically removed through a combination of mechanical polishing and chemical etching and the exposed epitaxial surface coated with an anti-reflection coating to avoid optical losses.

The hybridization process required to combine the IR active III-V or II-VI material with the silicon ROIC imposes many limitations and costs on the technology. First, while smaller sizes have been achieved, the indium bump width is practically limited to roughly 10 μm or greater due to yield considerations, which is several times larger than the optimal pixel size in the 2-5 μm range. Next, there can be a significant mismatch in thermal coefficient of expansion of the two material systems leading to bump failure or delamination after multiple cool-down cycles. Thirdly, strain, defect, or dipole formation at the epoxy-semiconductor interface can dramatically degrade surface electronic properties of the narrow gap IR material. The die-level nature of the hybridization process also adds considerable expense to the process, which relies on highly specialized equipment to achieve micron-level parallelicity and lateral alignment over inches of material under hundreds of pounds of force.

GeSn compounds are a potential optoelectronic material that can be grown directly on Si substrates, which would be compatible with current Si CMOS technology. GeSn alloys with 7 to 15% Sn composition grown under slight tensile strain have direct bandgaps with strong optical absorption from 1.6 to 5 μm, covering most of the all-important short-wave IR (SWIR) and mid-wave IR (MWIR) bands. The epitaxial growth of high quality, direct bandgap GeSn on Si would allow for the direct integration of IR optoelectronics with Si CMOS circuitry, eliminating many of the difficulties and costs associated with hybridized optoelectronic device structures. GeSn optoelectronics on Si would have the added benefits of lower cost (no longer need to produce separate III-VIII-VI materials), smaller size/more devices (no longer limited by bonding process), and greater speed/functionality (joint operation of light detection/emission with digital control).

A review of the published literature in this field can be confounding because the field is evolving. Early results were on obtaining more Sn in Ge in the hopes of exceeding 8% Sn and realizing a direct bandgap. Compressive strain, however, required more than 10% Sn in Ge to observe a direct bandgap signature. Only a few groups have successfully grown GeSn alloys with greater than 10% Sn. Studies of low Sn content films (less than 8%) may not be relevant to optoelectronically viable high Sn content films (greater than 10%). Although the patent literature appears to suggest the basic concept of growing GeSn on GeSn/SiGeSn/Ge by CVD (chemical vapor deposition), in practice, GeSn is only grown on GeSn or Ge by CVD. Furthermore, it is not clear that there are patents for growth by molecular beam epitaxy (MBE), because MBE is not the preferred growth method for the Si industry.

### U.S. Pat. No. 5,548,128 Direct-Gap Germanium-Tin Multiple-Quantum-Well Electro-Optical Devices on Silicon or Germanium Substrates

This might be the initial patent that started all experimental efforts to produce GeSn materials. The patent calls for quantum well device designs where tensile and compressive stresses in alternating layers of 5-40 nm are envisioned to obtain strain balance. They aren't specifically talking about SiGeSn but instead are referring to Si with Ge, Ge alone, and Sn with Ge.

### U.S. Pat. No. 6,897,471 Strain-Engineered Direct-Gap Ge/SnₓGe₁₋ₓ Heterodiode and Multi-Quantum-Well Photodetectors, Laser, Emitters and Modulators Grown on Sn_{y}Si_{z}Ge_{1-y-z}-Buffered Silicon

This is the first experimentally derived patent to produce GeSn, but there is a lot of what's possible in device design given that some material can now be produced. They mention use of a virtual substrate (but it's of Ge) in the low temperature growth by CVD (not MBE). They do say that the composition is up to 15% Sn (MBE can go higher). They do mention SiGeSn but never demonstrate its use. In fact, they state “the ternary has not been mapped out.” They do mention tensile Ge and strain relaxed GeSn (MBE can do that as well as tensile GeSn and SiGeSn).

### U.S. Pat. No. 7,582,891 Materials and Optical Devices Based on Group IV Quantum Wells Grown on Si—Ge—Sn Buffered Silicon

This patent is all about the new practice of growing GeSn and SiGeSn by CVD. They utilize a limited set of growth conditions (Sn concentration 2-4%, Si concentration 2× or 4× greater than Sn; and T<400 C). They describe the possibility of growing SiGeSn on GeSn, GeSn on GeSi, and SiGeSn on GeSi (MBE can do all of those, as well as GeSn on SiGeSn and GeSi on GeSn). Very little of what they describe had been demonstrated at the time and, even today, still has not been achieved in CVD.

### U.S. Pat. No. 7,589,003 GeSn Alloys and Ordered Phases With Direct Tunable Bandgaps Grown Directly on Silicon

This patent provides the experimental details of CVD growth of GeSn in the 250-350 C temperature window. They describe the growth of Ge on GeSn on Si(100) and Si(111) without the use of the Ge virtual substrate buffer. Later, it is realized that the Ge virtual substrate buffer plays a crucial role in the growth of GeSn films, and future CVD patents describe its need and use.

### U.S. Pat. No. 7,598,513 SiₓSn_{y}Ge.sub_{1-x-y} and Related Alloy Heterostructures Based on Si, Ge and Sn

This patent is a variant on conventional CVD referred to as UHV-CVD. MBE is a UHV (ultra-high vacuum) process, so in some ways this is an attempt to utilize the best from both methods. However, the molecular precursors used are different from what's used in CVD and in MBE resulting in a different growth process. The UHV-CVD method requires premixing the precursors and appears to produce a limited thickness of growth. Although, they claim to have produced a Si_{0.25}Ge_{0.54}Sn_{0.11} alloy on GeSn on Si in a 310-375 C growth temperature range.

### U.S. Pat. No. 8,029,905 GeSiSn-Based Compounds, Templates, and Semiconductor Structures

This patent proposes the possibility of producing (III-Vs or SiGe or Ge) on (GeSn or SiGeSn on GeSn). The idea is to grow films with matching lattice parameter on each other. A major failing in this concept is that the growth of III-Vs and SiGe are at temperatures far above the stability of GeSn and SiGeSn, which is why no experimental evidence of successfully doing this has ever been reported.

### U.S. Pat. No. 8,912,070 Method for Manufacturing Semiconductor Device

This patent proposes the possibility of creating a device based on using GeSn layer formed by implanting Sn into a film of Ge and laser annealing.

### U.S. Pat. No. 9,437,772 Method of Manufacture of Advanced Heterojunction Transistor and Transistor Laser

This patent proposes the potential device design for GeSn alloy use. It does not describe how any of the GeSn or SiGeSn films would be produced, nor does it provide the Si composition in any SiGeSn layer. Although, they do propose up to 20% Sn in GeSn without any detail.

### U.S. Pat. 9,793,115 Structures and Devices Including Germanium-Tin Films and Methods of Forming Same

This patent begins with a long list of prior art that covers most semiconductor growth. The patent does spell out some specific conditions for CVD growth of GeSn. However, it does not specifically address the creation and usage of a SiGeSn virtual substrate, but does mention the possible addition of Si to GeSn for other usage.

### U.S. Pat. No. 9,905,420 Methods of Forming Silicon Germanium Tin Films and Structures and Devices Including the Films

This patent must have been submitted with U.S. Pat. No. 9,793,115 because it now covers the creation of a SiGeSn film. However, the patent does not cover the usage of a SiGeSn film as a virtual substrate for the tensile and/or compressive strain in subsequent GeSn or SiGeSn films). What's missing in this patent and in all the previous CVD patents is the true problem for the growth of SiGeSn films, which is decomposition of molecular precursors (see FIG. 1). At the growth temperatures of GeSn by CVD (250-350° C.), there is almost no decomposition rate of SiH₄, as the rate is negligible. Because the SnH₄ decomposition is so rapid, SnD₄ is used, which has an order of magnitude slower decomposition, but it still deposits so much faster than GeH₄. To account for the different rates, the molecular flux ratio of GeH₄ to SnD₄ is typically 1000 to 1, which makes it extremely difficult to precisely control the composition. The reason MBE is such a valuable growth method is that it does not rely on the decomposition of molecular precursors for growth to happen. As such, MBE can grow any composition of Si, Ge, and Sn so long as the temperature is sufficient for crystallinity.

### U.S. Pat. No. 10,236,177 Methods for Depositing a Doped Germanium Tin Semiconductor and Related Semiconductor Device Structures

This is the most recent patent, and it discusses the p-type, boron doping of GeSn by CVD. It does not include SiGeSn, and it does not discuss n-type doping.

### BRIEF SUMMARY OF THE INVENTION

This invention disclosure describes the use of fully relaxed SiGeSn buffer layers grown on Si substrates to produce “virtual substrates” for the epitaxial growth of high quality GeSn films suitable for high performance infrared (IR) optoelectronic device technology directly integrated on silicon. One embodiment of the invention is the ability to create such virtual substrates with a slightly larger lattice constant than that of the target GeSn alloy in order to impose a precise degree of tensile strain. This is highly beneficial for optoelectronic devices using such GeSn alloys because it both promotes the formation of a direct band-gap and suppresses the formation of vacancies that degrade minority carrier lifetime.

The present invention provides several advantages. The first advantage of this invention is that the CVD growth process has great difficulty in growing SiGeSn, because the growth temperatures (280-350° C.) used for GeSn in CVD are not sufficient to decompose the Si molecular precursor (Si₂H₆) at greater than 400° C. When attempts to grow SiGeSn by CVD have been made, the Si precursor initially decomposes allowing some incorporation, but quickly ceases incorporating resulting in a graded Si composition or a stop in growth. MBE does not require molecular decomposition, and as such, all materials can be incorporated at low growth temperatures, with the only limit being the substrate must be hot enough to produce a crystalline structure.

The second advantage of this invention is that a Ge virtual substrate is not utilized. To produce a Ge virtual substrate, a thin Ge film (˜200-300 Å) is deposited at a low temperature (˜350° C.) followed by a thicker Ge layer (>800 Å) at a higher temperature (˜450° C.) ending with a very high temperature (800° C.) anneal. The high temperature anneal is not compatible with Si CMOS device fabrication. By grading the composition from pure Si to nearly pure Ge, strain relaxation can be obtained through misfit dislocation formation at interfaces without the high temperature annealing.

A third advantage of the SiGeSn virtual substrate is that it is chemically distinct from GeSn. The chemical etchant for GeSn is HCl in H₂O₂ and water. That same chemical etchant will remove the Ge virtual substrate. HCI/H₂O₂, however, does not react with the Si in SiGeSn leaving the alloy unetched. The SiGeSn layer can be etched by adding a small (1 part in 100) of HF to the HCI/H₂O₂ etchant. The HF/HCI/H₂O₂ etchant non-selectively etches the GeSn and SiGeSn at approximately the same rate, but the etching rate slows by more than 20× within the underlying graded GeSi/SiGe region. By using SiGeSn within a device structure, selective (GeSn vs. SiGeSn or SiGe vs. GeSn/SiGeSn) and non-selective etching is possible, providing more flexibility and control in device fabrication. Similar non-selective and selective etching is possible using plasma and reactive-ion etching (RIB). However, these techniques produce damage to the crystal structure, which can increase leakage currents in minority carrier devices.

A fourth advantage is related to the growth of unstrained GeSn alloys. A review of the literature for CVD growth of GeSn alloys with Sn concentrations greater than 10% will result in a range of bandgaps from 2.3 μm to 2.6 μm (0.54 eV-0.47 eV). Our initial GeSn alloy of 10% Sn had an absorption edge of 3.25 μm (0.38 eV). So, it is clear that the CVD growths are still compressively strained resulting in shorter wavelengths emissions (larger bandgaps). Because there is still compression in CVD growth, there is only a limited range of direct bandgaps obtainable. By growing strain-relaxed or under tension using MBE, a much larger range of direct bandgaps and wavelengths can be obtained.

These and other features and advantages of the invention, as well as the invention itself, will become better understood by reference to the following detailed description, appended claims, and accompanying drawings.

### BRIEF DESCRIPTION OF THE DRAWINGS

FIG. 1 shows the decomposition rates of SnH₄, GeH₄, and SiH₄ as a function of temperature. SiH₄ does not dissociate at GeSn growth temperatures resulting in limited incorporation and layer thickness. This figure shows that there is a small temperature window for GeSn growth and no window for SiGeSn growth using CVD.

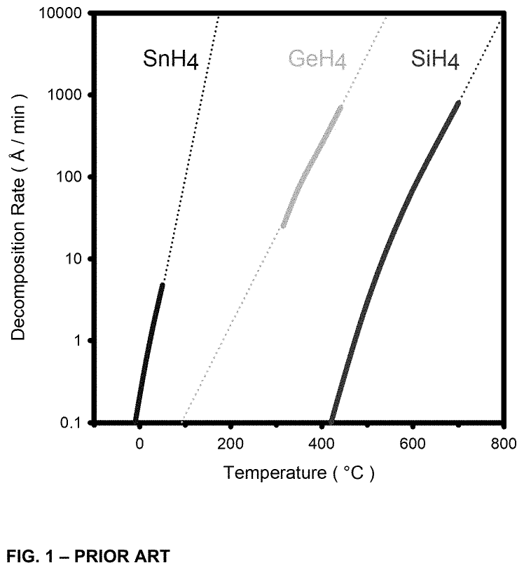

FIG. 2 shows the range of temperatures, Si flux rates, Ge flux rates, and Sn flux rates used by MBE in the growth of SiGeSn virtual substrates and GeSn films for optoelectronic applications.

### DETAILED DESCRIPTION OF THE INVENTION

The present invention provides for the use of SiGeSn buffer layers grown on Si substrates to produce virtual substrates for the epitaxial growth of high quality GeSn films suitable for high performance IR optoelectronic device technology directly integrated on silicon. One embodiment of this invention is a method for unstrained and tensile-strained MBE growth of GeSn compounds of 0-20% Sn content for a wide range of optoelectronic applications.

Group IV elements of Si, Ge, and alpha-Sn have diamond-like lattice constants of 5.431, 5.658, and 6.489 Å, respectively, but Sn is insoluble in Si (<0.01%) and nearly insoluble in Ge (<1.6%), requiring non-equilibrium, kinetically limited growth conditions possible in molecular beam epitaxy to obtain significant Sn concentrations in Group IV alloy films.

GeSn compounds, however, do not become a direct bandgap electronic material until the composition exceeds 8% Sn in GeSn, a challenging mandate given that the solubility of Sn in Ge is less than 1.6%. In order to incorporate a higher Sn concentration in Ge than that allowed by thermodynamics, GeSn must be grown under kinetically limited, non-equilibrium (KLNE) conditions. KLNE has been successfully achieved by both MBE and by CVD. CVD is the commercially utilized growth method for the fabrication of all Si-based technology. To deposit a GeSn film by CVD, a layer of Ge is first deposited on Si to create a “virtual substrate.” GeSn is then deposited from molecular fluxes of Ge and Sn chlorides (GeCl₄; SnCl₄) or hydrides/deuterides (Ge₂H₆; SnD₄) at temperatures between 350° C. and 280° C. As the growth temperature is lowered, more Sn can be incorporated into Ge to form GeSn. Because GeSn alloys have larger lattice parameters (spacing between the atoms) than the Ge virtual substrate on which they are deposited, these GeSn alloys are deposited under compressive stress. When grown under compressive stress, however, a Sn concentration greater than 8% is needed in order to achieve a direct bandgap electronic structure. Because compressive stress undermines the formation of a direct bandgap in GeSn, recent efforts have utilized a second layer of GeSn, which has been either partially or fully relaxed, to grow the GeSn optoelectronic device layer with less compressive stress in order to observe direct bandgap properties. Because compressive stress is still present, a different approach is necessary where the GeSn optoelectronic device layer is grown pseudomorphically under tensile strain upon on a second GeSn layer of greater Sn concentration.

Although MBE is not currently used in Si technology, it is used for many of the Ill-V and II-VI optoelectronic materials markets and is often utilized as the “test-bed” for developing CVD processes. With that in mind, another solution was sought for the dilemma of growing compressively strained GeSn on Ge virtual substrates. It was discovered that in the KLNE growth regime two factors were determining the amount of Sn incorporation in Ge. The first being compressive strain, which pushes Sn atoms out of Ge, but as the growth temperature is lowered, more Sn can be incorporated. The other factor is the adatom mobility of depositing Sn atoms on the surface. At the temperatures of growth, Sn atoms can move large distances on the Ge surface before incorporating. If and when, Sn atoms interact with each other on the Ge surface, the Sn atoms can form island clusters that will not incorporate into Ge. To prevent Sn atoms from moving and interacting, it was discovered that co-depositing Si with Sn (and Ge) was successful in preventing Sn clustering.

Using a co-deposition of Si with Ge and Sn, it was possible to incorporate 18% Sn with 15% Si and 67% Ge at a growth temperature of 135° C. resulting in a lattice parameter of 5.8 Å. There have been reports of higher Sn incorporation in Ge (by CVD up to 22%) but without Si, and there have been reports of SiGeSn growth but with much less Sn (by MBE up to 6%). The present method of pseudomorphic growth can be optimized, with the possibility that even higher Sn in the GeSn alloy can be obtained while varying both the Ge and Si. (It should be noted that Si and Ge are completely miscible in each other.) Additionally, the present method also allows for adjusting the Sn and Si composition to controllably obtain lower lattice parameters toward the Ge virtual substrate value of 5.6 Å. Thus, SiGeSn virtual substrates with a range of lattice parameters (5.8 Å-5.6 Å) was created that is under no strain for the subsequent growth of GeSn compounds of varying Sn concentrations. (The inclusion of Si in GeSn results in SiGeSn being an indirect bandgap electronic material and has poor optoelectronic properties.)

Unlike CVD GeSn growth, optoelectronic-relevant GeSn compounds can be grown on SiGeSn without film strain and under tensile strain. Tensile strain is the opposite of compressive strain, where it acts to make GeSn a direct bandgap material for lower Sn concentrations and enhances Sn incorporation. Theory predicts that any composition of GeSn under the appropriate amount of tension should have a direct bandgap and, therefore, be a viable optoelectronic material. Based on preliminary results, it is anticipated that varying the Sn concentration from 30% to 0% will give a range of band gaps from 0.10 eV to 0.80 eV (12 μm to 1.5 μm), which covers the midwave IR, shortwave IR, and telecommunication bands.

The process by which the SiGeSn virtual substrate is formed begins with a Si wafer that has been chemically cleaned to remove oxides and contaminants. The following is the general recipe for growth of the 18% Sn, 15% Si, and 67% Ge virtual substrate, but the final growth rates and temperatures can be adjusted to produce lower Sn concentration films:

1) Ramp wafer temperature to >600° C.

2) Begin depositing Si and grow a 200 Å buffer layer

3) Begin ramping down wafer temperature while continuously depositing Si at 0.5 Å/s

4) Begin continuous deposition of Ge at a low growth rate 0.05 Å/s

5) Ramp the Ge growth rate from 0.05 Å/s to 0.5 Å/s

6) When the Ge growth rate reaches 0.5 Å/s, begin ramping down the Si rate to 0.07 Å/s

7) With the sample temperature below 300° C., begin continuous deposition of Sn

8) Ramp the Sn growth rate from <0.01 Å/s up to 0.12 Å/s

9) Stabilize the growth temperature at 135° C. and deposit the SiGeSn alloy

10) Grow the SiGeSn alloy to a thickness>2000 Å/s for complete relaxation

11) Grow a GeSn optoelectronic alloy of any thickness and composition

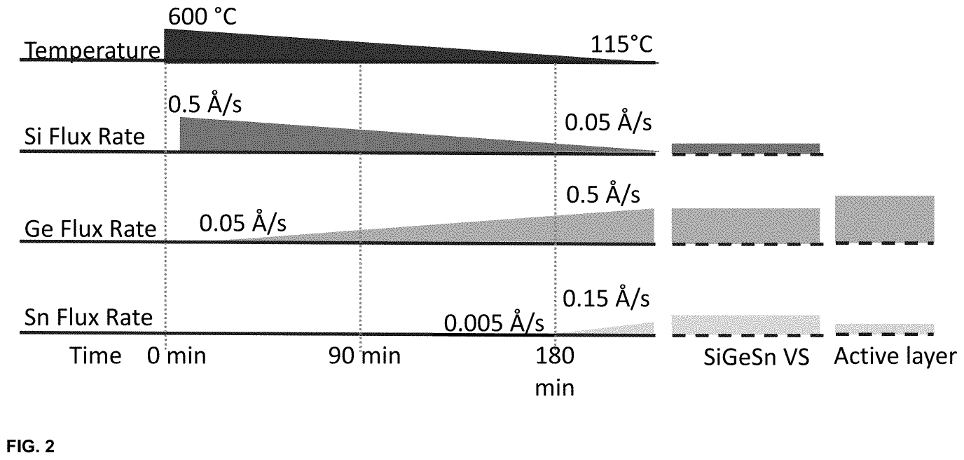

FIG. 2 shows the decreasing temperature and Si flux rate and increasing Ge and Sn flux rate for MBE growth of SiGeSn virtual substrates and GeSn films. Growing a SiGeSn virtual substrate requires precisely decreasing growth temperature and Si flux and precisely increasing Ge and Sn flux. MBE with e-beam evaporation can provide such precise flux variations, not limited by thermal inertia as in Knudsen cells.

The above descriptions are those of the preferred embodiments of the invention. Various modifications and variations are possible in light of the above teachings without departing from the spirit and broader aspects of the invention. It is therefore to be understood that the claimed invention may be practiced otherwise than as specifically described. Any references to claim elements in the singular, for example, using the articles “a,” “an,” “the,” or “said,” is not to be construed as limiting the element to the singular.

What is claimed as new and desired to be protected by Letters Patent of the United States is:

1. A method for growing a SiGeSn alloy, comprising:
depositing Si continuously to grow a buffer layer on the Si wafer;
ramping down the Si wafer temperature while continuously depositing Si;
depositing Ge continuously;
ramping up the Ge growth rate;
ramping down the Si growth rate;
when the Si wafer temperature is below 300° C., depositing Sn continuously;
ramping up the Sn growth rate;
stabilizing the Si wafer temperature and depositing a SiGeSn alloy on the Si wafer; and
growing the SiGeSn alloy to a thickness greater than 2000 Å,
wherein the SiGeSn alloy can be used for the growth of a GeSn optoelectronic alloy.

2. The method of claim 1, wherein the SiGeSn alloy is under no strain for the subsequent growing of the GeSn optoelectronic alloy.

3. The method of claim 1, wherein the SiGeSn alloy has a Sn concentration up to 20% by atomic composition.

4. The method of claim 1, wherein the SiGeSn alloy has a range of lattice parameters from 5.6 Å to 5.8 Å.

5. A method for growing a GeSn optoelectronic alloy, comprising:
growing a GeSn optoelectronic alloy on the SiGeSn alloy of claim 1, wherein the SiGeSn alloy has a lattice constant greater than or equal to the lattice constant of the GeSn optoelectronic alloy.

6. The method of claim 5, wherein the growing of the GeSn optoelectronic alloy is under tensile strain.

7. The method of claim 5, wherein the growing of the GeSn optoelectronic alloy is without strain.

8. The method of claim 5, wherein the GeSn optoelectronic alloy has a band gap between 0.10 ev to 0.80 eV.

9. A method for growing a SiGeSn alloy, comprising:
ramping a temperature of a Si wafer temperature to greater than 600° C.;
depositing Si continuously to grow a 200 Å buffer layer on the Si wafer;
ramping down the Si wafer temperature while continuously depositing Si at 0.5 Å/s;
depositing Ge continuously at a growth rate of 0.05 Å/s;
ramping the Ge growth rate from 0.05 Å/s to 0.5 Å/s;
when the Ge growth rate reaches 0.5 Å/s, ramping down the Si growth rate to 0.07 Å/s;
when the Si wafer temperature is below 300° C., depositing Sn continuously;
ramping the Sn growth rate from less than 0.01 Å/s up to 0.12 Å/s;
stabilizing the Si wafer temperature at 135° C. and depositing a SiGeSn alloy on the Si wafer; and
growing the SiGeSn alloy to a thickness greater than 2000 Å;
wherein the SiGeSn alloy can be used for the growth of a GeSn optoelectronic alloy of any Sn composition.

10. The method of claim 9, wherein the SiGeSn alloy is under no strain for the subsequent growing of the GeSn optoelectronic alloy.

11. The method of claim 9, wherein the SiGeSn alloy has a Sn concentration up to 20% by atomic composition.

12. The method of claim 9, wherein the SiGeSn alloy has a range of lattice parameters from 5.6 Å to 5.8 Å.
